(19) United States
(12) Patent Application Publication
(10) Pub. No.: US 2006/0185159 A1
(43) Pub. Date: Aug. 24, 2006

(54) Memory card insertion tool

(75) Inventors: Michael Anthony Correll, Hershey, PA (US); Richard Nicholas Whyne, Camp Hill, PA (US); Darrell Lynn Wertz, York, PA (US)

Correspondence Address: Robert J. Kapalka;Tyco Electronics Corporation, Suite 140, 4550 New Linden Hill Road, Wilmington, DE, 19808-2952, US

(73) Assignee: Tyco Electronics Corporation

(21) Appl. No.: 11/062,360

(22) Filed: Feb. 22, 2005

(51) Int. Cl. B23P 19/00; H05K 3/30

(52) U.S. Cl. 29/758; 29/832

(57) ABSTRACT

An insertion tool for installing an electronic package to a mating connector includes a body comprising a stop surface for the electronic package, and guide elements extending from the body adjacent the stop surface. The guide elements are configured to engage respective edges of the electronic package, and at least one substantially flat insertion pressing area extends from the body opposite the stop surface and extends outwardly from the body.

### BACKGROUND OF THE INVENTION

The invention relates generally to electrical connectors, and, more particularly, to a tool for inserting electrical components having a high density of connection pins to a circuit board.

Modern electronic devices, such as computers, include an array of electrical connectors interconnecting circuit boards and peripheral devices of the system. A primary circuit board, sometimes referred to as a motherboard, often utilizes a number of peripheral circuit boards, sometimes referred to as daughter cards, in operation. Electrical connectors establish communication between the motherboard and the daughter cards, and typically include many pin contacts which are inserted through holes in the motherboard to establish electrical contact therewith.

Memory sockets and memory modules, sometimes referred to as memory cards, are one type of peripheral device which are rapidly expanding to power newer and faster computer systems. Conventionally, the socket connectors have been installed to the motherboard and the modules are inserted into the socket connector by hand. New advances in dual in-line memory modules (DIMM), however, are not as amenable to installation by hand as previous DIMM devices. For example, dynamic random access memory (DRAM) modules, such as double date rate (DDR) modules having 184 interface contact positions, are now being replaced with newer modules (e.g., DDRII modules) having 240 interface contact positions. Due to a larger number of pin contacts in a relatively small area in the newer memory modules, larger insertion forces are generated when installing the memory modules into socket connectors on the motherboard. The increased insertion force to engage the memory module to the connector presents several problems which need to be addressed.

For example, the applied force to overcome the mechanical resistance of the memory modules to insertion into the connector on the motherboard tends to flex or bow the motherboard. Particularly with respect to the increasing use of ball grid array (BGA) technology to mount the modules to the motherboard, deflection of the motherboard as the memory modules are installed tends to fracture the BGA connections and compromise the integrity of the electrical connection between the memory modules and the motherboard.

Also, as a user installs such memory modules by hand, and as the user pushes down on the memory modules with a greater force to insert them into the socket connectors, it is difficult to keep the memory module properly aligned with the socket connectors. In particular, unless the insertion force is very carefully applied, the memory module can easily become tilted or angled with respect to the socket connector, which can further frustrate insertion of the memory module into the connector. This may lead the user to apply still more force to the module to attempt to insert the module into the connector, and potentially lead to damage to one or both of the memory module and the connector.

Additionally, the larger insertion forces may introduce discomfort and fatigue to the end users who must install them, either of which can lead to improper or incomplete installation of the memory modules. In turn, this can compromise the performance of the computer system and lead to customer dissatisfaction.

### BRIEF DESCRIPTION OF THE INVENTION

According to an exemplary embodiment, an insertion tool for installing an electronic package to a mating connector is provided. The insertion tool comprises a body comprising a stop surface for the electronic package, and guide elements extending from the body adjacent the stop surface. The guide elements are configured to engage respective edges of the electronic package, and at least one substantially flat insertion pressing area extends from the body opposite the stop surface and extends outwardly from the body.

Optionally, the body is substantially planar, and the at least one insertion pressing area comprises a pair of insertion pressing areas, the pair of insertion pressing areas separated from one another along an upper edge of the body. The body may comprise a curved upper edge, and a side edge adjacent to the at least one insertion pressing area, the side edge being recessed adjacent to and beneath the at least one insertion pressing area, thereby providing an opening proximate to the insertion pressing areas. The guide elements may comprise bias elements configured to engage the electronic package, and the electronic package may be a memory module.

According to another exemplary embodiment, an insertion tool for installing an electronic package to a mating connector is provided. The insertion tool comprises a body comprising a stop surface for the electronic package, and guide elements extending from the body adjacent the stop surface. The guide elements are configured to engage respective edges of the electronic package, and a first substantially flat insertion pressing area and a second substantially flat insertion pressing area are provided. The first and second insertion pressing areas extend from the body opposite the stop surface. The insertion pressing areas extend outwardly from the body and are configured to distribute loading force applied to the first and second insertion pressing areas evenly over the stop surface as the electronic package is installed to the connector.

According to still another exemplary embodiment, an electronic package insertion tool assembly comprises an electronic package, and an insertion tool comprising a body comprising a stop surface, and guide elements extending from the body adjacent the stop surface. The guide elements are configured to engage respective edges of the electronic package, and first and second substantially flat insertion pressing areas are provided and extend from the body opposite the stop surface. The insertion pressing areas extend outwardly from the body and are configured to distribute loading force applied to the first and second insertion pressing areas evenly over the stop surface when the electronic package is received in the guide elements and the electronic package is installed to a mating connector.

### BRIEF DESCRIPTION OF THE DRAWINGS

FIG. 1 is a perspective view of an electronic package insertion tool formed in accordance with an exemplary embodiment of the invention.

FIG. 2 is another perspective view of the tool shown in FIG. 1.

FIG. 3 is a detail view of the portion A of the tool shown in FIG. 2.

FIG. 4 is perspective view of the tool shown in FIG. 1 with an exemplary electronic package being loaded therein.

FIG. 5 illustrates the tool assembled to the electronic package.

FIG. 6 is a perspective view of the tool being used to install the electronic package to a connector.

FIG. 7 illustrates the tool and electronic package being installed to the connector.

FIG. 8 illustrates the tool being removed from the electronic package.

FIG. 9 illustrates the tool being gripped by a user.

### DETAILED DESCRIPTION OF THE INVENTION

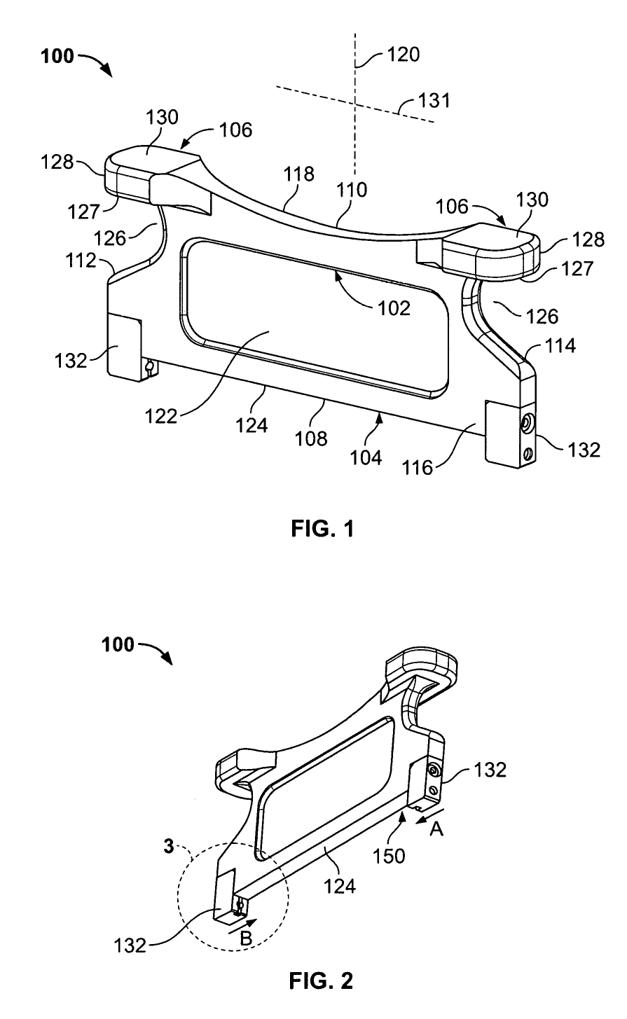

FIG. 1 is a perspective view of an electronic package insertion tool 100 formed in accordance with an exemplary embodiment of the invention. While the insertion tool 100 is particularly advantageous for installing memory modules, such as the aforementioned DDRII memory modules having 240 interface contact positions, it is recognized that the tool 100 may be beneficial when installing other electronic packages. The following description is therefore provided solely for the purpose of illustration, and the invention is not intended to be limited to any particular end use or application with a specific electronic package.

In an exemplary embodiment, the tool 100 includes a frame or body 102 formed of a nonconductive material (e.g., plastic) into a generally flat or planar tool engagement portion 104 and pressing areas 106 extending from the tool engagement portion 104. The tool engagement portion 104 includes a bottom edge 108, a top edge 110 opposite the bottom edge 108, and left and right edges 112, 114 connecting the top and bottom edges. Opposite faces or surfaces 116 and 118 extend on the tool engagement portion 104 between the top, bottom, left and right edges 108, 110, 112, 114, and the surfaces 116 and 118 extend substantially parallel to one another and are also generally parallel to a vertical axis 120 which bisects the tool engagement portion 104 into substantially equal and symmetrical halves.

Additionally, in the illustrated embodiment, the tool engagement portion 104 of the tool body 102 includes a generally rectangular opening or aperture 122 extending through the body between the opposite faces or surfaces 116, and 120. While the opening 122 may be beneficial for gripping the tool 100 by inserting one's fingers through the opening 122 and wrapping one's fingers around the remainder of the tool engagement portion 104, the opening or aperture 122 is considered optional to achieve the overall benefit and advantage of the invention. That is, in alternative embodiments, the tool engagement portion 104 is fabricated to a solid construction that does not include the opening or aperture 122.

The bottom edge 108 of the tool engagement portion 104 is flat and smooth, thereby forming a stop surface 124 on a lower end of the tool 100. The stop surface 124 engages a portion of the electronic package (not shown in FIG. 1) when loaded into the tool as described below. In a further and/or alternative embodiment, the stop surface is contoured and includes, for example, slots or keying features which engage complementary portions of the electronic package. Such keying features may provide additional support to the electronic package during installation with the tool 100 which may further mitigate out of plane deflection of the electronic package when engaged to a mating connector.

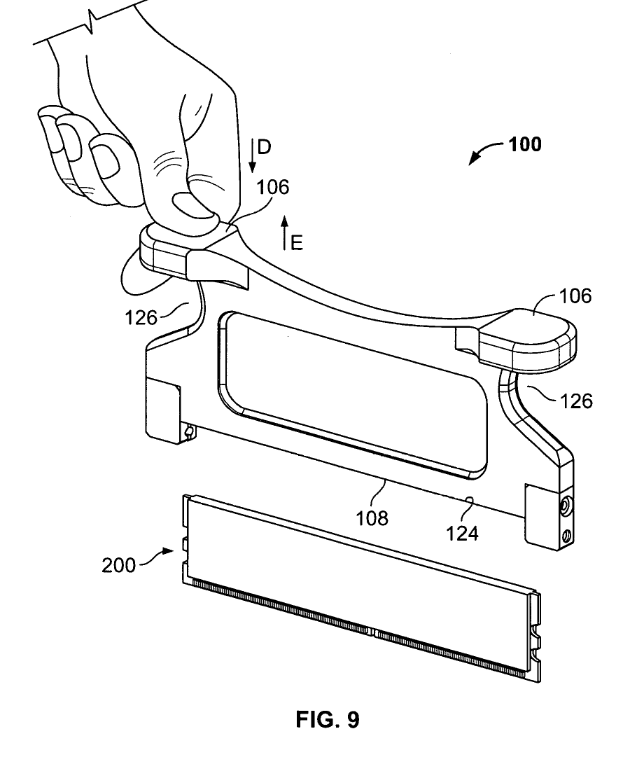

The side edges 112 and 114 of the tool engagement portion 104 are inwardly curved or sloped toward the vertical axis 120 such that the side edges 112 and 114 become closer to one another in an upper region of the tool 100 (e.g., near the pressing areas 104) than at the lower region of the tool 100 (e.g., near the stop surface 124. As such, the side edges 112 and 114 each define recessed areas or openings 126 beneath the pressing areas 106 which provide finger access to the pressing areas 106 from below, as illustrated in FIG. 9.

Returning to FIG. 1, the pressing areas 106 extend outwardly from the generally flat faces or surfaces 116 and 118 of the tool engagement portion 104. That is, the pressing areas 106 are outwardly flared from the tool engagement portion 104 such that the pressing areas 106 have a greater dimension measured perpendicular to the surfaces 116 and 118 that the remainder of the tool 100. The pressing areas 106 include bottom surfaces 127 overhanging the recesses 126, rounded side edges 128 extending from the bottom surfaces 127, and flat and smooth top surfaces 130 located proximate the side edges 112 and 114 of the tool 100. The top surfaces 130 are coplanar to one another and extend parallel to a horizontal axis 132. Thus, the top surfaces 130 of the pressing areas 106 extend substantially perpendicular to the side surfaces or faces 116, 118 of the tool engagement portion 104.

In an exemplary embodiment, the top edge 110 of the tool engagement portion 104 is curved downwardly in a concave form away from the top surfaces 130 of the pressing areas 106. The top edge 110 of the tool engagement portion 104 therefore forms a discontinuity in the upper surface of the tool 100, and the pressing areas 106 are separated from one another by the curved top edge 110. As such, distinct pressing areas 106 are defined by the user on the top surfaces 130 of the pressing areas 106. Distinct pressing areas 106 separated from one another promotes a uniform distribution of force along the stop surface 124 when the tool is used.

Guide elements 132 are attached to a lower end of the tool 100 on either end of the stop surface 124, and the guide elements 132 are constructed to grip side edges of the electronic package in the manner described below. While the guide elements 132 in the illustrated embodiment are separately provided and attached to the tool engagement portion 104, in further and/or alternative embodiments, the guide elements 132 may be integrally formed into the tool construction.

FIG. 2 is another perspective view of the tool 100 illustrating the flat engagement surface 124 and the guide elements 132 at either end thereof. The guide elements 132 define a channel 150 therebetween which cooperates with the stop surface 124 to receive the electronic package.

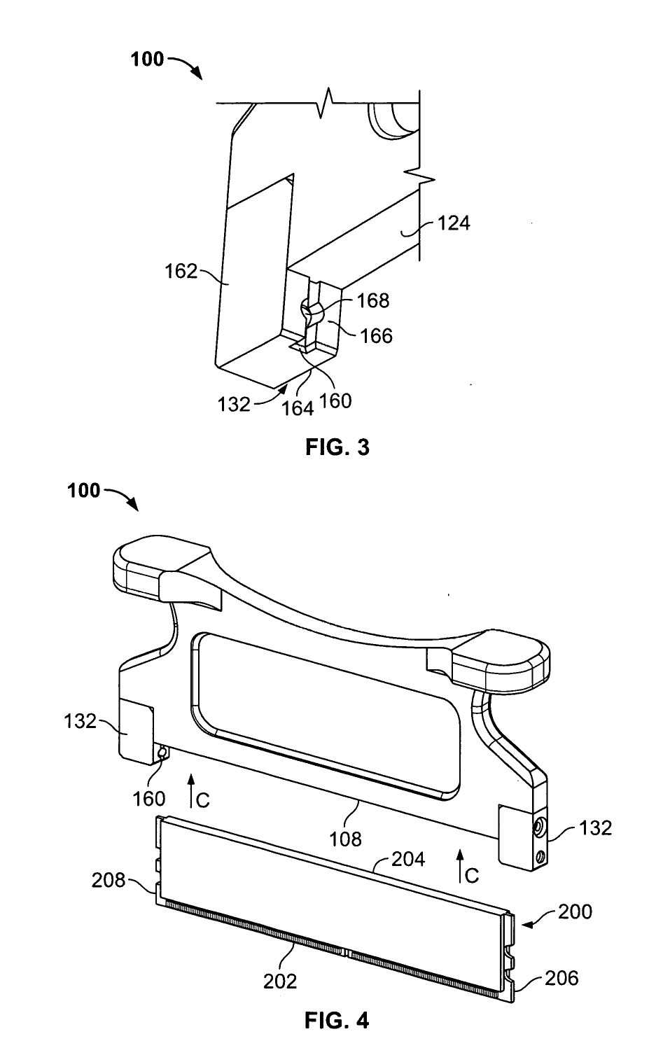

As shown in FIG. 3, the guide elements 132 include a vertically extending alignment slot 160 which extends approximately equidistant from opposite side edges 162 and 164 of each guide element 132. The alignment slot 160 includes a flared section 166 which accommodates a bias element 168 therein. The bias element 168 in one embodiment is a known spring element which is deflected within the alignment slot 160 when a side edge of the electronic package is inserted in the alignment slot 160. Deflection of the bias element 168 generates a bias force in the direction of arrows A and B (FIG. 2) when the electronic packages is loaded into the tool 100. The bias elements 168 therefore provide a gripping forces on the side edges of an electronic package to ensure that the electronic package is engaged to the tool for handling in the installation process described below.

While spring loaded guide elements 132 have been found to be advantageous in one embodiment, it is understood that in alternative embodiments the bias elements 168 could be omitted and the electronic package could be secured to the tool by other means known in the art.

FIG. 4 is perspective view of the tool 100 with an exemplary electronic package 200 being loaded therein. As shown in FIG. 4, the electronic package is a generally rectangular packages having a bottom mating edge 202, a top edge 204 opposite the bottom edge 202, and side edges 206 and 208 interconnecting the top and bottom edges 202 and 204. The bottom edge 202 includes a number of contact pads or traces which are engaged to mating surfaces of a connector (not shown in FIG. 4) when the electronic package 200 is installed to a printed circuit board (not shown in FIG. 4). In an exemplary embodiment the electronic package is a known DDRII memory module card having 240 interface contact positions, although it is recognized that the tool 100 may be beneficial for installing other electronic packages in different embodiments.

In a loading position as shown in FIG. 4, the electronic package 200 is generally aligned with the bottom edge 108 of the tool 100 such that as the electronic package 200 is moved toward the tool bottom edge 108 in the direction of arrows C, the side edges 206 and 208 of the electronic package 200 are received in the alignment slots 160 of the tool guide elements 132, and consequently the electronic package 200 is properly aligned with and centered with respect to the tool 100.

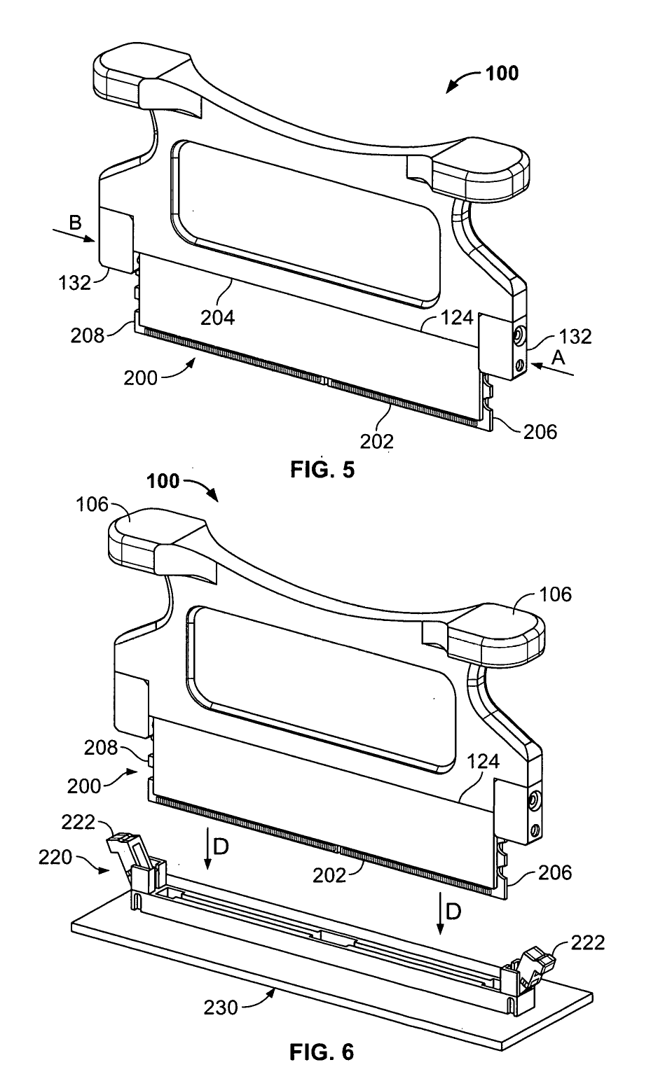

FIG. 5 illustrates the tool 100 assembled to the electronic package 200 wherein the package side edges 206 and 208 of the are engaged to the tool guide elements 132. The bias elements 168 (shown in FIG. 3) of each of the guide elements 132 generate a retention force on the package side edges 206 and 208 in the direction of arrows A and B so that the electronic package 200 may be lifted and handled together with the tool 100. The top edge 204 of the electronic package 200 is in abutting contact with the tool engagement surface 124.

FIG. 6 is a perspective view of the tool 100 being used to install the electronic package 200 to a connector 220 mounted on a circuit board 230 in a known manner. The connector 220 is a known socket or receptacle connector which is configured to receive the bottom edge 202 of the connector in a known manner, and also includes latching elements 222 which lockably engage the side surfaces 206, 208 of the electronic package 200 when the package 200 is received in the connector 220.

The electronic package 200 is aligned with the connector 220 using the tool 100, and the package 200 is installed into the connector 220 by pressing downward upon the pressing areas 106 of the tool in the direction of arrows D, as shown in FIGS. 6 and 9. Specifically, as illustrated in FIG. 9, the thumb and forefinger of the respective hands of a user may be used in conjunction with the respective pressing areas 106 and recesses 126 of the tool 100 to apply a downward force with the tool 100. Substantially uniform insertion force is produced on the tool bottom edge 108 and the engagement surface 124 with the package 200 to insert the package 200 in the connector without flexing or bowing the circuit board 230, and without out-of-plane deformation of the package 200 itself. Further, misalignment of the package 200 with respect to the tool 100 and or the connector 220 is substantially avoided, thereby allowing insertion of the package 200 into the connector 220 with relative ease despite an increased insertion force required to install the package 200. Thus, damage to the electrical connections between the connector 220 and the circuit board 230 is avoided, together with damage to the package 200 itself, while conveniently providing for installation of the package 200. Discomfort and fatigue in installing the packages 200 is avoided with a low cost and easy to use tool 100.

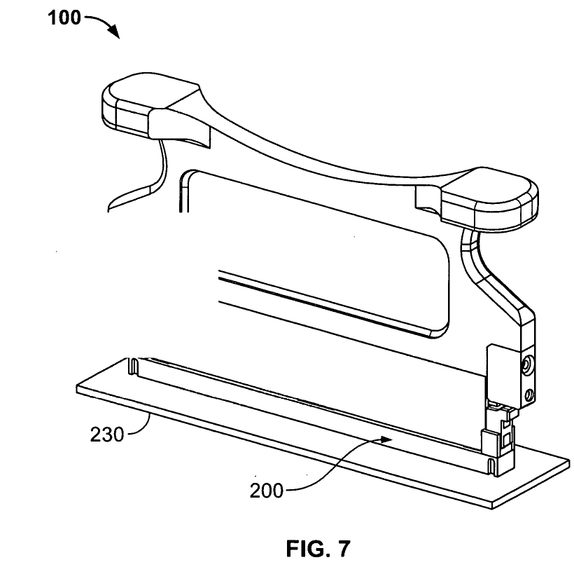

FIG. 7 illustrates the tool 100 and the electronic package 200 installed in the connector 200 with the locking latches 222 of the connector 200 firmly securing the electronic package 200 to the connector 220.

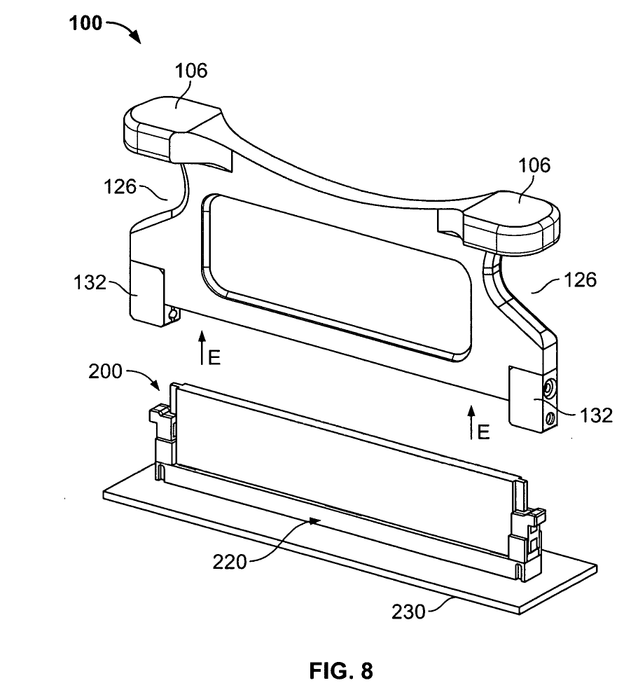

FIG. 8 illustrates the tool being removed from the electronic package 200 after the package 200 is properly installed to the connector 220. A user's fingers may be placed in the recesses 126 beneath the tool pressing areas 106, and by pulling the tool 100 upward in the direction of arrows E as shown in FIGS. 6 and 9, the tool guide elements 132 may be disengaged from the electronic package 200 to separate the package 200 from the tool 100.

While the invention has been described in terms of various specific embodiments, those skilled in the art will recognize that the invention can be practiced with modification within the spirit and scope of the claims.

What is claimed is:

1. An insertion tool for installing an electronic package to a mating connector, said insertion tool comprising:
a body comprising a stop surface for the electronic package;
guide elements extending from said body adjacent said stop surface, said guide elements configured to engage respective edges of the electronic package; and
at least one substantially flat insertion pressing area extending from said body opposite said stop surface, said insertion pressing area extending outwardly from said body.

2. An insertion tool in accordance with claim 1 wherein said body is substantially planar.

3. An insertion tool in accordance with claim 1 wherein said at least one insertion pressing area comprises a pair of insertion pressing areas, said pair of insertion pressing areas separated from one another along an upper edge of said body.

4. An insertion tool in accordance with claim 1 wherein said body comprises a curved upper edge.

5. An insertion tool in accordance with claim 1 wherein said body further comprises a side edge adjacent to said at least one insertion pressing area, said side edge being recessed adjacent to and beneath said at least one insertion pressing area, thereby providing an opening proximate to said at least one insertion pressing area.

6. An insertion tool in accordance with claim 1 wherein said guide elements comprise bias elements configured to engage the electronic package.

7. An insertion tool in accordance with claim 1 wherein the electronic package is a memory module, said guide elements configured to receive the memory module and retain the memory module while a user installs the memory module to the connector via pressing down on said at least one insertion pressing area.

8. An insertion tool for installing an electronic package to a mating connector, said insertion tool comprising:
a body comprising a stop surface for the electronic package;
guide elements extending from said body adjacent said stop surface, said guide elements configured to engage respective edges of the electronic package; and
a first substantially flat insertion pressing area and a second substantially flat insertion pressing areas, said first and second insertion pressing areas extending from said body opposite said stop surface, said insertion pressing areas extending outwardly from said body and configured to distribute loading force applied to said first and second insertion pressing areas evenly over said stop surface as the electronic package is installed to the connector.

9. An insertion tool in accordance with claim 8 wherein said body is substantially planar.

10. An insertion tool in accordance with claim 8 wherein said first and second insertion pressing areas are separated from one another along an upper edge of said body.

11. An insertion tool in accordance with claim 8 wherein said body comprises a curved upper edge extending between said first and second insertion pressing area.

12. An insertion tool in accordance with claim 8 wherein said body further comprises opposite side edges adjacent to each of said first and second insertion pressing areas, each of said side edges being recessed adjacent to and beneath the respective first and second insertion pressing areas, thereby providing finger openings proximate each of said at first and second insertion pressing area.

13. An insertion tool in accordance with claim 8 wherein said guide elements comprise bias elements configured to engage the electronic package.

14. An insertion tool in accordance with claim 8 wherein the electronic package is a memory module, said guide elements configured to receive the memory module and retain the memory module while a user installs the memory module to the connector via pressing down on said at least one insertion pressing area.

15. An electronic package insertion tool assembly comprising:
an electronic package; and
an insertion tool comprising a body comprising a stop surface, guide elements extending from said body adjacent said stop surface, said guide elements configured to engage respective edges of said electronic package, and first and second substantially flat insertion pressing areas extending from said body opposite said stop surface;
wherein said insertion pressing areas extend outwardly from said body and are configured to distribute loading force applied to said first and second insertion pressing areas evenly over said stop surface when said electronic package is received in said guide elements and said electronic package is installed to a mating connector.

16. An insertion tool assembly in accordance with claim 15 wherein said body is substantially planar.

17. An insertion tool in accordance with claim 15 wherein said first and second insertion pressing areas are separated from one another along an upper edge of said body.

18. An insertion tool in accordance with claim 15 wherein said body comprises a curved upper edge extending between said first and second insertion pressing area.

19. An insertion tool in accordance with claim 15 wherein said body further comprises opposite side edges adjacent to each of said first and second insertion pressing areas, each of said side edges being recessed adjacent to and beneath the respective first and second insertion pressing areas, thereby providing finger openings proximate each of said at first and second insertion pressing area.

20. An insertion tool in accordance with claim 15 wherein the electronic package is a memory module.
